(19) United States
(12) Patent Application Publication
(10) Pub. No.: US 2025/0301870 A1
(43) Pub. Date: Sep. 25, 2025

(54) DISPLAY APPARATUS

(71) Applicant: Samsung Display Co., LTD., Yongin-si (KR)

(72) Inventors: Jiye LEE, Yongin-si (KR); Hosuk MAENG, Yongin-si (KR); Kyunghwan MOON, Yongin-si (KR)

(21) Appl. No.: 19/058,388

(22) Filed: Feb. 20, 2025

(30) Foreign Application Priority Data
Mar. 21, 2024 (KR) 10-2024-0039257

(51) Int. Cl. H10K 59/131; H01L 23/498; H10K 59/95

(52) U.S. Cl. CPC H10K 59/131; H01L 23/49838; H10K 59/95; H01L 23/4985

(57) ABSTRACT

A display apparatus including a peripheral area with a reduced area is provided. The display apparatus includes a first substrate, first pads on the first substrate along a first edge of the first substrate, second pads on the first substrate along the first edge and between the first edge and the first pads, a second substrate, third pads on the second substrate along a second edge of the second substrate, fourth pads on the second substrate along the second edge and between the second edge and the third pads, a first film including an end portion electrically connected to the first pads and the other end portion electrically connected to the third pads, and a second film including an end portion electrically connected to the second pads and the other end portion electrically connected to the fourth pads.

This application claims priority to Korean Patent Application No. 10-2024-0039257, filed on Mar. 21, 2024, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a display apparatus with a reduced peripheral area.

### 2. Description of the Related Art

In general, a display apparatus includes a display area, wherein images are displayed, and a peripheral area outside the display area. In such a display apparatus, the ratio of the peripheral area to the display area may be relatively decreased by increasing the area of the display area.

### SUMMARY

Existing display apparatuses have a problem in that it is not easy to display high-quality images while relatively reducing the size of the peripheral area of the display apparatuses. Decreasing the size of the peripheral area of a display apparatus may reduce the ability of the display apparatus to effectively display high-quality images.

One or more embodiments are to overcome various problems including the aforementioned one and provide a display apparatus with a reduced peripheral area. However, this is merely an example, and the scope of the present disclosure is not limited thereto.

Additional aspects will be set forth in part in the description which follows and, in part, will be apparent from the description, or may be learned by practice of the presented embodiments of the disclosure.

According to one or more embodiments, a display apparatus includes a first substrate, first pads on the first substrate along a first edge of the first substrate, second pads on the first substrate along the first edge, the second pads being between the first edge and the first pads, a second substrate, third pads on the second substrate along a second edge of the second substrate, fourth pads on the second substrate along the second edge, the fourth pads being between the second edge and the third pads, a first film including an end portion electrically connected to the first pads and another end portion electrically connected to the third pads, and a second film including an end portion electrically connected to the second pads and another end portion electrically connected to the fourth pads.

The first film may overlap the second film.

A width in a second direction of the first film may be greater than a width in the second direction of the second film, wherein the second direction is perpendicular to a first direction which extends from the first substrate to the second substrate.

An area of the first film may be greater than an area of the second film.

The first film may cover the second film.

A portion of the second film, which overlaps the second pads, may be between the first substrate and the first film.

A portion of the second film, which overlaps the fourth pads, may be between the second substrate and the first film.

The second pads may correspond to spaces between the first pads.

The fourth pads may correspond to spaces between the third pads.

The display apparatus may further include first display elements on the first substrate, wherein the second substrate may include a circuit board.

The display apparatus may further include first display elements on the first substrate and second display elements on the second substrate.

The display apparatus may further include a driving driver on the first substrate.

The first film and the second film may be configured to transmit electrical signals from the driving driver to the second display elements.

The display apparatus may further include a flexible printed circuit board electrically connected to a third edge of the first substrate.

The third edge may be opposite the first edge, with respect to the center of the first substrate.

The first film and the second film may be configured to transmit electrical signals from the flexible printed circuit board to the second display elements.

An area of a main display area of the first substrate, where the first display elements are arranged, may be greater than an area of a sub-display area of the second substrate, where the second display elements are arranged.

The first film and the second film may be bendable such that a rear surface of the second substrate may be on a rear surface of the first substrate.

The first film and the second film may be flexible.

The first pads, the second pads, the third pads, and the fourth pads may extend in a direction parallel to the first edge and the second edge. A width of the first film in the direction may be greater than a width of the second film in the direction.

Other aspects, features, and advantages other than those described herein will become apparent from the following detailed description, claims and drawings for carrying out the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are schematic perspective views illustrating an exterior of a display apparatus, according to an embodiment;

FIG. 3 is a schematic plan view of a portion of a display apparatus according to an embodiment;

FIG. 4 is a schematic plan view of a portion of the display apparatus of FIG. 3;

FIG. 5 is a schematic cross-sectional view of the display apparatus of FIG. 4, taken along a line A-A′ of FIG. 4;

FIG. 6 is a schematic cross-sectional view of the display apparatus of FIG. 4, taken along a line B-B′ of FIG. 4;

FIG. 7 is a schematic cross-sectional view of the display apparatus of FIG. 4, taken along a line C-C′ of FIG. 4;

FIG. 8 is a schematic plan view of a portion of a display apparatus according to an embodiment; and

FIG. 9 is a schematic plan view of a portion of the display apparatus of FIG. 8.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described herein, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The attached drawings for illustrating embodiments of the disclosure are referred to in order to gain a sufficient understanding of the present disclosure, the merits thereof, and the objectives accomplished by the implementation of the disclosure. The disclosure may, however, be embodied in many different forms and should not be construed as being limited to the embodiments set forth herein.

Hereinafter, one or more embodiments of the disclosure will be described in detail with reference to the accompanying drawings. Like elements in the drawings denote like elements, and repeated descriptions thereof are omitted.

It will be understood that when a component, such as, for example, a layer, a film, a region, or a plate, is referred to as being “on” another component, the component can be directly on the other component or intervening components may be present thereon. Sizes of components in the drawings may be exaggerated for convenience of explanation. In other words, since sizes and thicknesses of elements in the drawings are arbitrarily illustrated for convenience of explanation, the following embodiments are not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

It will be understood that although the terms “first,” “second,” and the like may be used herein to describe various elements, these elements should not be limited by these terms, and the terms are used to distinguish one element from another.

It will be further understood that the terms “comprises” and/or “comprising” used herein specify the presence of stated features or components, but do not preclude the presence or addition of one or more other features or components.

In the present embodiment, an expression such as “A and/or B” indicates A, B, or A and B. An expression such as “at least one of A and B” indicates A, B, or A and B.

It will be understood that when a layer, region, or component is referred to as being connected to another layer, region, or component, it can be directly and/or indirectly connected to the other layer, region, or component. That is, for example, intervening layers, regions, or components may be present. For example, when a layer, region, or component is referred to as being electrically connected to another layer, region, or component, it can be directly or indirectly electrically connected to the other layer, region, or component.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within +30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially flat” means approximately or actually flat. The term “substantially extend in a direction” means approximately or actually extend in the direction.

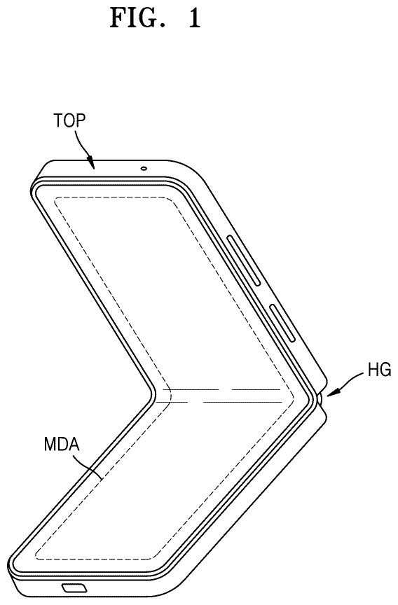

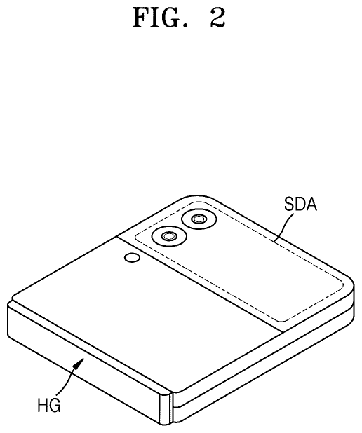

FIGS. 1 and 2 are schematic perspective views illustrating an exterior of a display apparatus, according to an embodiment. As illustrated in FIGS. 1 and 2, the display apparatus according to the present embodiment is a foldable display apparatus including a hinge HG and may be folded or unfolded along the hinge HG. The display apparatus according to the present embodiment may have a main display area MDA and a sub-display area SDA. The area of the main display area MDA may be greater than the area of the sub-display area SDA. FIG. 1 illustrates the main display area MDA folded at an angle of about 90 degrees, while FIG. 2 illustrates the display apparatus in a fully folded state. In an example in which the display apparatus is completely folded as illustrated in FIG. 2, the main display area MDA is located on the inside of the display apparatus such that the sub-display area SDA on the outside of the display apparatus is usable by the user. The display apparatus may also be fully unfolded such that the main display area MDA may become substantially flat. The display apparatus according to the present embodiment may be a mobile device such as, for example, a smartphone.

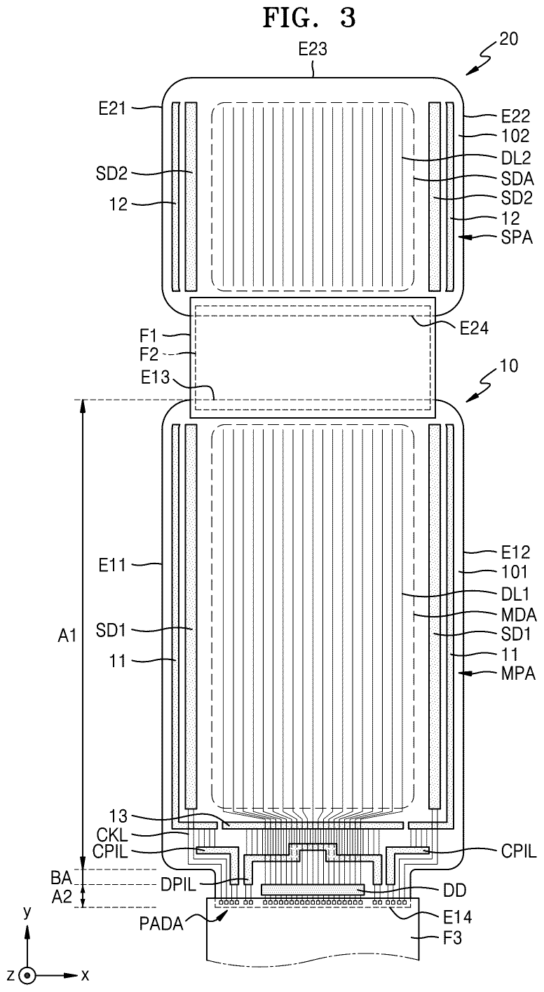

FIG. 3 is a schematic plan view of a portion of a display apparatus according to an embodiment. For example, the display apparatus of FIG. 3 may be a portion of the display apparatus illustrated in FIGS. 1 and 2, which is described herein in detail. The display apparatus according to the present embodiment may include a main display panel 10 and a sub-display panel 20.

The main display panel 10 may have a main display area MDA including a plurality of first display elements and a main peripheral area MPA outside the main display area MDA. It may be understood that a first substrate 101 of the main display panel 10 includes the main display area MDA and the main peripheral area MPA described herein.

In the main peripheral area MPA, a first scan driver SD1, a driving driver DD, and various lines may be arranged. The main peripheral area MPA may have a pad area PADA, and in the pad area PADA, a flexible printed circuit board F3 or an electronic device such as, for example, the driving driver DD may be electrically attached. In the main peripheral area MPA, a common voltage input line CPIL, a first common voltage supply line 11, a driving voltage input line DPIL, a first driving voltage supply line 13, and the like may also be arranged. Various lines including a clock signal line CKL to be input to the first scan driver SD1 may pass through the main peripheral area MPA.

The driving driver DD may include an integrated circuit for driving the main display panel 10. Such an integrated circuit may be a data driving integrated circuit for generating a data signal, but one or more embodiments are not limited thereto. The first substrate 101 may have a first main edge E11 and a second main edge E12 which substantially extend in a first direction (a y-axis direction) and face each other and may also have a third main edge E13 and a fourth main edge E14 which substantially extend in a second direction (an x-axis direction) crossing the first direction and appear to connect the first main edge E11 and the second main edge E12. The fourth main edge E14 may be opposite to the third main edge E13, with respect to the center of the first substrate 101. The driving driver DD may be mounted in the main peripheral area MPA to be adjacent to the fourth main edge E14 of the first substrate 101. It may be understood that the aforementioned flexible printed circuit board F3 is electrically connected to the fourth main edge E14 of the first substrate 101. The fourth main edge E14 may be referred to as a third edge for convenience.

For reference, it may be understood that FIG. 3 is a plan view illustrating the first substrate 101 during the manufacture. In a finished display apparatus or an electronic apparatus, e.g., a smartphone, which includes a display apparatus, a portion of the first substrate 101 and the like may be bent to reduce the area of the main peripheral area MPA which is recognized by a user. For example, the main peripheral area MPA may include a bending area BA, and the bending area BA may be located between the pad area PADA and the main display area MDA. In this case, the first substrate 101 is bent in the bending area BA such that the first area A1 on one side of the first substrate 101 with respect to the bending area BA may overlap the second area A2 located on the other side of the first substrate 101.

For example, the first substrate 101 is bent in the bending area BA such that at least a portion of the second area A2 including the pad area PADA may overlap the first area A1 including the main display area MDA. In this case, the bending direction is set such that the pad area PADA is located behind the main display area MDA. Accordingly, the user recognizes that the main display area MDA occupies most of the display apparatus. The driving driver DD is mounted on the same plane as the display surface of the main display area MDA, but as the main display panel 10 is bent in the bending area BA, the driving driver DD may be located towards the rear surface of the main display area MDA.

The first substrate 101 may include various materials that are flexible or bendable, and examples of the materials include polymer resin such as, for example, polyethersulfone, polyacrylate, polyetherimide, polyethylene naphthalate, polyethylene terephthalate, polyphenylene sulfide, polyarylate, polyimide, polycarbonate, or cellulose acetate propionate. Various modifications may be made to the first substrate 101, and for example, the first substrate 101 may have a multilayered structure that includes two layers including the above polymer resin and a barrier layer including an inorganic material (e.g., silicon oxide, silicon nitride, silicon oxynitride, or the like) and arranged between the two layers. Furthermore, when the first substrate 101 is not bent, the first substrate 101 may include glass or the like.

The main display area MDA may be substantially rectangular or square shaped. Edges of the main display area MDA may generally have shapes that are similar to edges of a rectangle or a square. Accordingly, the first substrate 101 may be substantially rectangular or square shaped. The edges of the main display area MDA may generally have shapes that are similar to edges of circular, oval, or polygonal shapes.

As described herein, the first substrate 101 may have the first main edge E11 and the second main edge E12 which substantially extend in the first direction (the y-axis direction) and face each other and may also have the third main edge E13 and the fourth main edge E14 which substantially extend in the second direction (the x-axis direction) crossing the first direction and appear to connect the first main edge E11 and the second main edge E12. The pad area PADA may be a portion of the main peripheral area MPA of the first substrate 101 which is adjacent to the fourth main edge E14. According to necessity, the first substrate 101 has bending portions between the first main edge E11 and the fourth main edge E14 and between the second main edge E12 and the fourth main edge E14 such that the first substrate 101 may be easily bent in the bending area BA. Accordingly, as illustrated in FIG. 3, the width of the first substrate 101 in the second area A2 in the second direction (the x-axis direction) may be less than the width of the first substrate 101 in the first area A1 in the second direction (the x-axis direction).

Hereinafter, an organic light-emitting display apparatus is described as an example of the display apparatus, but the display apparatus is not limited thereto. As another example, the display apparatus may be a display apparatus such as, for example, an inorganic light-emitting display apparatus, an inorganic EL display apparatus, or a quantum dot light-emitting display apparatus. For example, an emission layer of a display element of the display apparatus may include an organic material or an inorganic material. In some aspects, the display apparatus may include an emission layer and quantum dots arranged in a path of light emitted from the emission layer.

In the main display area MDA, a plurality of pixels are arranged. Each of the pixels may be a sub-pixel and include a first display element such as, for example, an organic light-emitting diode OLED and a pixel circuit electrically connected to the first display element. The pixel may emit, for example, red light, green light, blue light, or white light. The pixels may be electrically connected to outer circuits arranged in the main peripheral area MPA. In the main peripheral area MPA, the first scan driver SD1, the first common voltage supply line 11, the first driving voltage supply line 13, and the like may be arranged.

The first scan driver SD1 may extend along the first main edge E11 of the first substrate 101. The first scan driver SD1 may be configured to provide a scan signal to the pixels through a scan line (not illustrated) extending into the main display area MDA in the second direction (the x-axis direction). The first scan driver SD1 may be positioned along the second main edge E12 of the first substrate 101. In this case, some of the pixels in the main display area MDA may be electrically connected to the first scan driver SD1 near the first main edge E11, and others of the pixels may be electrically connected to the first scan driver SD1 near the second main edge E12. Alternatively, near the second main edge E12 of the first substrate 101, an emission control driver is located instead of the first scan driver SD1, and thus, the emission control driver may be configured to provide emission control signals to the pixels in the main display area MDA through an emission control line (not illustrated) that is substantially parallel to the scan line.

A plurality of main pads may be located in the pad area PADA of the main display panel 10. Such main pads may not be covered by an insulating layer and may be exposed such that the main pads may be electrically connected to the flexible printed circuit board F3. That is, the pads of the flexible printed circuit board F3 may be electrically connected to the main pads of the main display panel 10.

The flexible printed circuit board F3 is configured to transmit signals from the controller or power to the main display panel 10. Control signals generated by the controller may be transmitted to the driving driver DD and the first scan driver SD1 through the flexible printed circuit board F3. In some aspects, the controller may provide a common voltage (ELVSS) to the first common voltage supply line 11 through a common voltage input line CPIL and provide the common voltage to a common electrode of organic light-emitting diodes in the main display area MDA. The controller may provide a driving voltage (ELVDD) to the first driving voltage supply line 13 through the driving voltage input line DPIL and provide the driving voltage to pixel circuits in the main display area MDA through first driving voltage lines (not illustrated) extending from the first driving voltage supply line 13 into the main display area MDA in the first direction (the y-axis direction). The first driving voltage lines may be substantially parallel to the first data lines DL1. For reference, as illustrated in FIG. 3, the first common voltage supply line 11 may extend substantially in the first direction (the y-axis direction) along each of the first main edge E11 and the third main edge E13. Conversely, the first common voltage supply line 11 may have a loop shape with one open side in the direction towards the fourth main edge E14 and thus may extend along the first main edge E11, the third main edge E13, and the second main edge E12.

The controller may generate data signals, and the generated data signals may be transmitted to the driving driver DD and the pixels in the main display area MDA through the first data lines DL1 extending in the first direction (the y-axis direction) and crossing the main display area MDA. The drawing illustrates that the clock signal line CKL receives a clock signal through the main pad and is configured to transmit the clock signal to the first scan driver SD1, but unlike the illustration, the clock signal line CKL may receive the clock signal from the driving driver DD and may be configured to transmit the clock signal to the first scan driver SD1.

Similar to the main display panel 10, the sub-display panel 20 may have the sub-display area SDA, where a plurality of pixels are arranged, and the sub-peripheral area SPA outside the sub-display area SDA. It may be understood that a second substrate 102 of the sub-display panel 20 includes the sub-display area SDA and the sub-peripheral area SPA described herein. In the sub-peripheral area SPA, a second scan driver SD2 and various lines may be arranged. Although not illustrated in FIG. 3, similar to the placement of the first driving voltage supply line 13, a second driving voltage supply line may also be arranged in the sub-peripheral area SPA as applicable or suitable for the display apparatus.

The second substrate 102 may include various materials that are flexible or bendable, and examples of the materials include polymer resin such as, for example, polyether sulfone, polyacrylate, polyetherimide, polyethylene naphthalate, polyethylene terephthalate, polyphenylene sulfide, polyarylate, polyimide, polycarbonate, or cellulose acetate propionate. Various modifications may be made to the second substrate 102, and for example, the second substrate 102 may have a multilayered structure that includes two layers including the above polymer resin and a barrier layer including an inorganic material (e.g., silicon oxide, silicon nitride, silicon oxynitride, or the like) and arranged between the two layers. Furthermore, when the second substrate 102 is not flexible, the second substrate 102 may include glass or the like.

The sub-display area SDA may be substantially rectangular or square shaped. Edges of the sub-display area SDA may generally have shapes that are similar to edges of a rectangle or a square. Accordingly, the second substrate 102 may be substantially rectangular or square shaped. In some example implementations, the edges of the sub-display area SDA may generally have shapes that are similar to edges of circular, oval, or polygonal shapes. Moreover, when components such as, for example, a camera and illuminance sensor are located in the sub-display area SDA, openings may be located in the sub-display area SDA to accommodate the components according to necessity. For reference, FIG. 2 illustrates that a camera is located in the sub-display area SDA.

The second substrate 102 may have a first sub-edge E21 and a second sub-edge E22 which substantially extend in the first direction (the y-axis direction) and face each other and may also have a third sub-edge E23 and a fourth sub-edge E24 which substantially extend in the second direction (the x-axis direction) crossing the first direction and appear to connect the first sub-edge E21 and the second sub-edge E22. The fourth sub-edge E24 of the second substrate 102 may be adjacent to the third main edge E13 of the first substrate 101.

In the sub-display area SDA, a plurality of pixels are arranged. Each of the pixels may be a sub-pixel and include a second display element such as, for example, an organic light-emitting diode OLED and a pixel circuit electrically connected to the second display element. The pixel may emit, for example, red light, green light, blue light, or white light. The pixels may be electrically connected to outer circuits arranged in the sub-peripheral area SPA. In the sub-peripheral area SPA, the second scan driver SD2 and the second common voltage supply line 12 may be arranged, and in some example implementations, the second driving voltage supply line may also be arranged.

The second scan driver SD2 may extend along the first sub-edge E21 of the second substrate 102. The second scan driver SD2 may be configured to provide scan signals to the pixels through a scan line (not illustrated) extending into the sub-display area SDA in the second direction (the x-axis direction). The second scan driver SD2 may be positioned along the second sub-edge E22 of the second substrate 102. In this case, some of the pixels in the sub-display area SDA may be electrically connected to the second scan driver SD2 near the first sub-edge E21, and others of the pixels may be electrically connected to the second scan driver SD2 near the second sub-edge E22. Alternatively, near the second sub-edge E22 of the second substrate 102, an emission control driver is located instead of the second scan driver SD2, and thus, the emission control driver may be configured to provide emission control signals to the pixels in the sub-display area SDA through an emission control line (not illustrated) that is substantially parallel to the scan line.

Unlike the main display panel 10 on which the driving driver DD is mounted, the sub-display panel 20 may not include a driving driver. Instead, an electrical signal from the driving driver DD mounted on the main display panel 10 may be transmitted to the sub-display panel 20 and may be transmitted to the pixels in the sub-display area SDA of the sub-display panel 20 through a second data line DL2 extending in the first direction (the y-axis direction) and crossing the sub-display area SDA. To this end, as illustrated in FIG. 3, a first film F1 and a second film F2 may electrically connect the main display panel 10 and the sub-display panel 20, which is described herein in detail.

For reference, it may be understood that FIG. 3 is a plan view illustrating the first substrate 101 and the second substrate 102 during the manufacture. In a finished display apparatus or an electronic apparatus, for example, a smartphone, which includes a display apparatus, the first film F1 and the second film F2 are bent to make the rear surface of the sub-display panel 20 face the rear surface of the main display panel 10, thereby implementing the electronic device described herein with reference to FIGS. 1 and 2. That is, the rear surface of the second substrate 102 may be positioned on the rear surface of the first substrate 101. Bending portions of the first film F1 and the second film F2 may be positioned on portions marked as TOP of the display apparatus of FIG. 1. In this case, at least a portion of the flexible printed circuit board F3 attached to the pad area PADA of the main display panel 10 or at least a portion of a circuit board electrically connected to the flexible printed circuit board F3 may be between the main display panel 10 and the sub-display panel 20.

The first common voltage supply line 11 of the main display panel 10 may be electrically connected to the second common voltage supply line 12 of the sub-display panel 20 through the first film F1 and/or the second film F2 and may be configured to provide the common voltage (ELVSS) to the common electrode of the organic light-emitting diode in the sub-display area SDA. As illustrated in FIG. 3, the second common voltage supply line 12 may substantially extend along each of the first sub-edge E21 and the third sub-edge E23 in the first direction (the y-axis direction). Conversely, the second common voltage supply line 12 may have a loop shape with one open side in the direction towards the fourth sub-edge E24 and thus may extend along the first sub-edge E21, the third sub-edge E23, and the second sub-edge E22.

Moreover, the first driving voltage lines extending into the main display area MDA from the first driving voltage supply line 13 in the first direction (the y-axis direction) may also be electrically connected to the second driving voltage supply lines of the sub-display panel 20 through the first film F1 and/or the second film F2. Accordingly, the driving voltage (ELVDD) may be supplied to the pixel circuits in the sub-display area SDA through the second driving voltage lines (not illustrated) extending from the second driving voltage supply line into the sub-display area SDA in the first direction (the y-axis direction). The second driving voltage lines may be substantially parallel to the second data lines DL2.

The first scan driver SD1 of the main display panel 10 may also be electrically connected to the second scan driver SD2 of the sub-display panel 20 through the first film F1 and/or the second film F2. It may be understood that a clock signal, which is applied to the first scan driver SD1, is applied to the second scan driver SD2 of the sub-display panel 20 through the first film F1 and/or the second film F2.

For reference, the common voltage (ELVSS), the driving voltage (ELVDD), and/or the clock signal may be electrical signals transmitted from the flexible printed circuit board F3 to the main display panel 10. Alternatively, the electrical signal may be applied to the driving driver DD, which is mounted on the main display panel 10, through the flexible printed circuit board F3, and by using the electrical signal, the data signal generated by the driving driver DD may be transmitted to the second display elements of the sub-display panel 20 through the first film F1 and the second film F2. Therefore, it may be understood that the first film F1 and the second film F2 are configured to transmit the electrical signals from the flexible printed circuit board F3 to the second display elements of the sub-display panel 20.

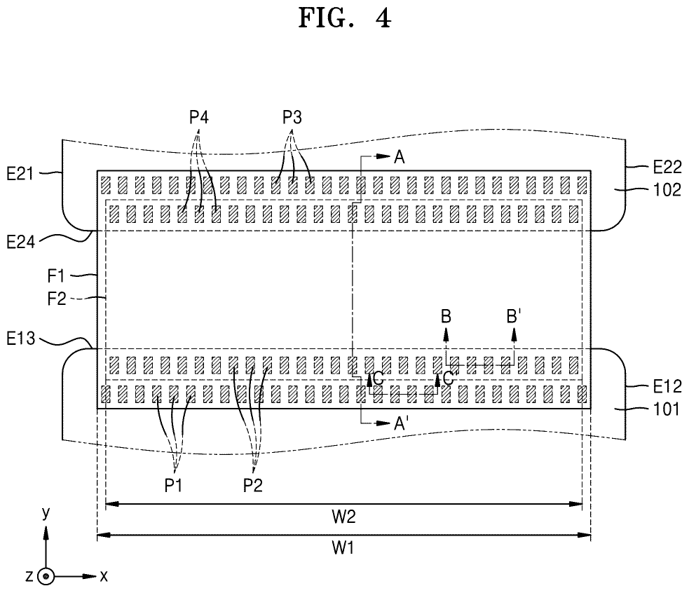

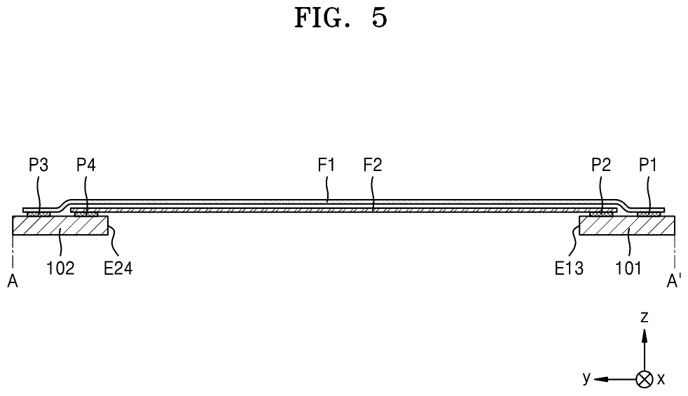

FIG. 4 is a schematic plan view of a portion of the display apparatus of FIG. 3, and FIG. 5 is a schematic cross-sectional view of the display apparatus of FIG. 4, taken along a line A-A′ of FIG. 4.

The first pads P1 and the second pads P2 may be arranged on the first substrate 101. In detail, the first pads P1 may be arranged along the third main edge E13, near the third main edge E13 that is an edge of the first substrate 101 towards the second substrate 102. That is, the first pads P1 may be arranged near the third main edge E13 in the second direction (the x-axis direction). The second pads P2 may be arranged between the third main edge E13 and the first pads P1. The second pads P2 may also be arranged along the third main edge E13, that is, in the second direction (the x-axis direction). For reference, the third main edge E13 may be referred to as the first edge for convenience. The first pads P1 and the second pads P2 may not be covered by the insulating layer and may be exposed, thus being electrically connected to the first film F1 and/or the second film F2 as described herein. For convenience of illustration, the first pads P1 and the second pads P2 are omitted from FIG. 3.

Third pads P3 and fourth pads P4 may be arranged on the second substrate 102. In detail, the third pads P3 may be arranged along the fourth sub-edge E24, near the fourth sub-edge E24 that is an edge of the second substrate 102 towards the first substrate 101. That is, the third pads P3 may be arranged near the fourth sub-edge E24 in the second direction (the x-axis direction). The fourth pads P4 may be arranged between the fourth sub-edge E24 and the third pads P3. The fourth pads P4 may also be arranged along the fourth sub-edge E24, that is, in the second direction (the x-axis direction). For reference, the fourth sub-edge E24 may be referred to as the second edge for convenience. The third pads P3 and the fourth pads P4 may not be covered by the insulating layer and may be exposed, thus being electrically connected to the first film F1 and/or the second film F2. For convenience of illustration, the third pads P3 and the fourth pads P3 are omitted from FIG. 3.

An end portion of the first film F1 (in the −y direction) may be electrically connected to the first pads P1 on the first substrate 101, and the other end portion of the first film F1 (in the +y direction) may be electrically connected to the third pads P3 on the second substrate 102. An end portion of the second film F2 (in the −y direction) may be electrically connected to the second pads P2 on the first substrate 101, and the other end portion of the second film F2 (in the +y direction) may be electrically connected to the fourth pads P4 on the second substrate 102. The first film F1 may include conductive lines, and the conductive lines may electrically connect the first pads P1 on the first substrate 101 to the third pads P3 on the second substrate 102. The second film F2 may also include conductive lines, and the conductive lines may electrically connect the second pads P2 on the first substrate 101 to the fourth pads P4 on the second substrate 102. That is, one conductive line of the first film F1 may electrically connect any one of the first pads P1 on the first substrate 101 to its corresponding one of the third pads P3 on the second substrate 102. One conductive line of the second film F2 may electrically connect any one of the second pads P2 on the first substrate 101 to its corresponding one of the fourth pads P4 on the second substrate 102.

As described herein, the driving driver DD including an integrated circuit configured to drive the main display panel 10 may be mounted on the first substrate 101. The integrated circuit may be the data driving integrated circuit configured to generate data signals, and the data signals from the driving driver DD may be transmitted to the pixels in the main display area MDA of the main display panel 10 including the first substrate 101 through the first data line DL1.

Unlike the main display panel 10 on which the driving driver DD is mounted, the sub-display panel 20 may not include a driving driver. Therefore, there is a need for a medium for transmitting data signals to the pixels in the sub-display area SDA of the sub-display panel 20. In the case of the display apparatus according to the present embodiment, the first film F1 and the second film F2 may serve to transmit the electrical signals from the driving driver DD to the second display elements in the sub-display area SDA.

In detail, the driving driver DD mounted on the main display panel 10 may generate data signals to be transmitted to the pixels in the sub-display area SDA of the sub-display panel 20. The data signals may be transmitted to the second data lines DL2 of the sub-display panel 20 through at least some of the first data lines DL1 of the main display panel 10 and at least some of the conductive lines of the first film F1 and the conductive lines of the second film F2. In an example in which the number of first data lines DL1 of the main display panel 10 is equal to the number of second data lines DL2 of the sub-display panel 20, the first data lines DL1 may be electrically connected to the second data lines DL2 one-to-one by the conductive lines of the first film F1 and the conductive lines of the second film F2.

As described herein, the second scan driver SD2 extending along the first sub-edge E21 of the second substrate 102 may be configured to provide scan signals to the pixels through the scan line (not illustrated) extending into the sub-display area SDA in the second direction (the x-axis direction). The clock signal and the like used for the generation of scan signals by the second scan driver SD2 may be transmitted to the second scan driver SD2 through at least some of the first pads P1 or the second pads P2 on the first substrate 101, the conductive lines of the first film F1 and/or the conductive lines of the second film F2, and at least some of the third pads P3 or the fourth pads P4 on the second substrate 102.

The common voltage (ELVSS) to be applied to the common electrode of the organic light-emitting diodes in the sub-display area SDA may be applied through the second common voltage supply line 12 of the sub-display panel 20. To this end, embodiments of the present disclosure support providing an electrical connection between the second common voltage supply line 12 of the sub-display panel 20 and the first common voltage supply line 11 of the main display panel 10. The first common voltage supply line 11 of the main display panel 10 may be electrically connected to the second common voltage supply line 12 of the sub-display panel 20 through at least some of the first pads P1 or the second pads P2 on the first substrate 101, the conductive lines of the first film F1 and/or the conductive lines of the second film F2, and at least some of the third pads P3 or the fourth pads P4 on the second substrate 102.

The driving voltage (ELVDD) to be applied to the organic light-emitting diodes in the sub-display area SDA may be applied through the second driving voltage lines that extend into the sub-display area SDA and are substantially parallel to the second data lines DL2. To this end, embodiments of the present disclosure support providing an electrical connection between the second driving voltage lines of the sub-display panel 20 and the first driving voltage lines of the main display panel 10. The first driving voltage lines of the main display panel 10 may be electrically connected to the second driving voltage lines of the sub-display panel 20 through at least some of the first pads P1 or the second pads P2 on the first substrate 101, the conductive lines of the first film F1 and/or the conductive lines of the second film F2, and at least some of the third pads P3 or the fourth pads P4 on the second substrate 102.

As described herein, the first driving voltage supply line 13 may be located in the main display panel 10, and the first driving voltage lines extend from the first driving voltage supply line 13 in the first direction (the y-axis direction) such that the first driving voltage lines may cross the main display area MDA. Similarly, the second driving voltage supply line (not illustrated) is located near the fourth sub-edge E24 in the sub-display panel 20, and the second driving voltage lines extend from the second driving voltage supply line in the first direction (the y-axis direction) such that the second driving voltage lines may cross the sub-display area SDA. In this case, the first driving voltage lines of the main display panel 10 may be electrically connected to the second driving voltage supply line of the sub-display panel 20 through at least some of the first pads P1 or the second pads P2 on the first substrate 101, the conductive lines of the first film F1 and/or the conductive lines of the second film F2, and at least some of the third pads P3 or the fourth pads P4 on the second substrate 102. In this case, the second driving voltage supply line may be located at different layers from the second data lines DL2 and thus be electrically insulated therefrom.

For reference, FIG. 4 does not show the conductive lines electrically connected to the first pads P1 and the second pads P2 on the first substrate 101 for convenience and the conductive lines electrically connected to the third pads P3 and the fourth pads P4 on the second substrate 102. For example, at least some of the first data lines DL1 of the first substrate 101 may be electrically connected to some of the first pads P1 and the second pads P2 on the first substrate 101 through the conductive lines, and the second data lines DL2 of the second substrate 102 may be electrically connected to some of the third pads P3 and the fourth pads P4 on the second substrate 102 through the conductive lines.

The display apparatus according to the present embodiment may be implemented without separate driving drivers or circuit boards for driving the sub-display panel 20, resulting in the reduction in manufacturing costs. In some aspects, because the main display panel 10 is electrically connected to the sub-display panel 20 by using the first film F1 and the second film F2 which may overlap each other, a display apparatus capable of displaying high-resolution images even on the sub-display panel 20 at a low cost may be implemented.

For example, unlike the display apparatus using the first film F1 and the second film F2 which overlap each other, it is possible to consider using a single film to electrically connect the main display panel 10 to the sub-display panel 20. However, in this case, because there is a limitation on the number of conductive lines that may be included in the single film, a problem may arise in which high-resolution images may not be displayed in the sub-display panel 20.

Alternatively, it may be considered that the single film includes conductive lines at different layers. For example, it may be considered to make the single film include a sufficient number of conductive lines by placing first conductive lines on a lower surface of the single film and second conductive lines on an upper surface of the single film.

In this case, however, because the lower surface of the single film comes in contact with the first pads P1 and the second pads P2 on the first substrate 101, there is a need for a configuration allowing pads located on the lower surface of the single film and electrically connected to the first pads P1 to be electrically connected to second conductive lines located on the upper surface of the single film through conductive layers in through holes penetrating the upper surface and the lower surface of the single film. Accordingly, portions for the through holes of the single film may be necessary for the single film, and such portions are positioned in the direction towards the center of the first substrate 101 (in the −y direction) with respect to the location of the first pads P1 on the first substrate 101. The positioning of such portions may result in an increase in the area of a portion of the single film that overlaps the first substrate 101, and such an increase may lead to an increase in the area of the main peripheral area MPA of the first substrate 101; thus, the ratio of the main display area MDA of the first substrate 101 may decrease. The single film including the conductive lines on both surfaces, the through holes, and the conductive layers in the through holes has a complicated structure, and using the single film may cause a significant increase in manufacturing costs for display apparatuses.

In the case of the display apparatus according to the present embodiment, because the first film F1 and the second film F2 overlapping each other are used, the aforementioned problems may be effectively prevented from occurring. Because the conductive lines are present on the lower surfaces of the first film F1 and the second film F2 (and not present on the upper surfaces of the first film F1 and the second film F2) and the pads on the lower surfaces of the first film F1 and the second film F2 are electrically connected to the first pads P1, the second pads P2, the third pads P3, or the fourth pads P4, the structure of each of the first film F1 and the second film F2 may be simplified, enabling low manufacturing costs. In some aspects, because the display apparatus according to the present embodiment may be implemented without being dependent on securing portions for through holes, the ratio of the main display area MDA in the first substrate 101 may remain high. Moreover, because the first film F1 and the second film F2 which overlap each other are used, the number of conductive lines included in the first film F1 and the second film F2 may be sufficient. To this end, a display apparatus capable of displaying high-resolution images even on the sub-display panel 20 at a low cost may be realized.

As illustrated in FIG. 4, in the second direction (the x-axis direction) perpendicular to the first direction (the y-axis direction) from the first substrate 101 to the second substrate 102, the width W1 of the first film F1 may be greater than the width W2 of the second film F2. This width gap (e.g., difference between the width W1 and the width W2) prevents the second film F2 from being exposed outside the first film F1 such that it appears (e.g., according to a plan view) as if a single film is located between the main display panel 10 and the sub-display panel 20. Thus, the probability of defects occurring during the manufacturing of the display apparatus may be reduced and manufacturing efficiency may be improved.

As described herein, the first film F1 is electrically connected to the first pads P1 and the third pads P3, the second film F2 is electrically connected to the second pads P2 and the fourth pads P4, the second pads P2 are between the first pads P1 and the third main edge E13, and the fourth pads P4 are between the third pads P3 and the fourth sub-edge E24. Therefore, as illustrated in FIGS. 3 and 4, when the first film F1 and the second film F2 are in the flat state, the length of the first film F1 in the first direction (the y-axis direction) may be greater than the length of the second film F2 in the first direction (the y-axis direction). In the states described herein, when the width W1 of the first film F1 becomes greater than the width W2 of the second film F2, the area of the first film F1 may eventually be greater than the area of the second film F2. In this case, the first film F1 covers the second film F2. Specifically, a portion of the second film F2 overlapping the second pads P2, which is an end portion of the second film F2 towards the main display panel 10, may be between the first substrate 101 and the first film F1. Similarly, a portion of the second film F2 overlapping the fourth pads P4, which is an end portion of the second film F2 towards the sub-display panel 20, may be between the second substrate 102 and the first film F1.

As illustrated in FIG. 4, the second pads P2 may correspond to the spaces between the first pads P1. As described herein, through use of the first film F1 and the second film F2 overlapping each other to establish the electrical connection between the main display panel 10 and the sub-display panel 20, embodiments of the present disclosure support placing a target number of conductive lines for cases in which it is impossible (e.g., due to space constraints) or not cost effective to place the necessary number of conductive lines in a single film. In the display apparatus according to the present embodiment, the first film F1 and the second film F2 overlapping each other are used, and thus, a sufficient number of conductive lines (e.g., a number of conductive lines suitable for implementing the display apparatus) may be located in the first film F1 and the second film F2. Embodiments of the present disclosure support establishing electrical connections between the conductive lines and the first pads P1 or the second pads P2 on the first substrate 101 while effectively preventing unintended short circuits. In this case, for example, by widening the distances between the first pads P1 and the second pads P2 on the first substrate 101 as much as possible (e.g., based on manufacturing tolerances, design constraints, and the like), unintended short circuits between the first pads P1 and the second pads P2 may be prevented.

To this end, as illustrated in FIG. 4, the second pads P2 may be arranged to correspond to the spaces between the first pads P1. In other words, one first pad P1 may be arranged to correspond to the space between two adjacent second pads P2 when considering the positions of the first pads P1 and the second pads P2 in the second direction (the x-axis direction). Thus, compared to when both the first pad P1 and the second pad P2 that is closest to the first pad P1 are positioned on a virtual straight line extending in the first direction (the y-axis direction), embodiments of the present disclosure support increasing the distance (in the first direction (y-axis direction) and/or the second direction (x-axis direction)) between the first pad P1 and the second pad P2 to a greater extent.

Expressed another way, the respective sizes of the second pads P2 in the second direction (x-axis direction) may be equal to spacings between adjacent first pads P2 in the second direction (x-axis direction). In some aspects, respective spacings between the second pads P2 in the second direction (x-axis direction) may be equal to respective spacings between adjacent first pads P1 in the second direction (x-axis direction).

In some embodiments, a virtual line extending in the first direction (y-axis direction) from a vertical edge (y-axis edge) of a first pad P1 may intersect a second pad P2 which is closest to the first pad P1. For example, the virtual line extending in the first direction (y-axis direction) from the vertical edge (y-axis edge) of the first pad P1 may intersect a vertical edge (y-axis edge) of the second pad P2 which is closest to the first pad P1 or a vertical edge (y-axis edge) of another second pad P2 which is adjacent the second pad P2.

In some alternative and/or additional embodiments, the second pads P2 may each be arranged to correspond to an area which is different from (e.g., smaller than) the spaces between the first pads P1. Expressed another way, the respective sizes of the second pads P2 in the second direction (x-axis direction) may be different from (e.g., smaller than) spacings between adjacent first pads P2 in the second direction (x-axis direction). For example, embodiments of the present disclosure support implementations in which a virtual line extending in the first direction (y-axis direction) from a first pad P1 does not intersect a second pad P2 which is closest to the first pad P1. That is, for example, the virtual line extending in the first direction (y-axis direction) from the vertical edge (y-axis edge) of the first pad P1 may pass between a vertical edge (y-axis edge) of a second pad P2 which is closest to the first pad P1 and a vertical edge (y-axis edge) of another second pad P2 which is adjacent the second pad P2.

This arrangement may be applied to the location relationship between the third pads P3 and the fourth pads P4 in the same manner. That is, as illustrated in FIG. 4, the fourth pads P4 may correspond to the spaces between the third pads P3. In the display apparatus according to the present embodiment, the first film F1 and the second film F2 overlapping each other are used, and thus, a sufficient number of conductive lines may be located in the first film F1 and the second film F2. Embodiments of the present disclosure support establishing electrical connections between the conductive lines and the third pads P3 or the fourth pads P4 on the second substrate 102 while effectively preventing unintended short circuits. In this case, for example, by widening the distances between the third pads P3 and the fourth pads P4 on the second substrate 102 as much as possible (e.g., based on manufacturing tolerances, design constraints, and the like), unintended short circuits between the third pads P3 and the fourth pads P4 may be prevented.

To this end, as illustrated in FIG. 4, the fourth pads P4 may be arranged to correspond to the spaces between the third pads P3. In other words, one third pad P3 may be arranged to correspond to the space between two adjacent fourth pads P4 when considering the positions of the third pads P3 and the fourth pads P4 in the second direction (the x-axis direction). Thus, compared to when both one third pad P3 and one fourth pad P4 that is closest to the third pad P3 are positioned on a virtual straight line extending in the first direction (the y-axis direction), embodiments of the present disclosure support increasing the distance (in the first direction (y-axis direction) and/or the second direction (x-axis direction)) between the third pad P3 and the fourth pad P4 to a greater extent.

Expressed another way, the respective sizes of the fourth pads P4 in the second direction (x-axis direction) may be equal to spacings between adjacent third pads P3 in the second direction (x-axis direction). In some aspects, respective spacings between the fourth pads P4 in the second direction (x-axis direction) may be equal to respective spacings between adjacent third pads P3 in the second direction (x-axis direction).

Additionally, or alternatively, the respective sizes of the fourth pads P4 in the second direction (x-axis direction) may be different from (e.g., smaller than) spacings between adjacent third pads P3 in the second direction (x-axis direction). In some aspects, respective spacings between the fourth pads P4 in the second direction (x-axis direction) may be different from respective spacings between adjacent third pads P3 in the second direction (x-axis direction).

Aspects of the sizes and spacings associated with the fourth pads P4 and the third pads P3 may include aspects of sizes and spacings described herein in association with the second pads P2 and the first pads P1, and repeated descriptions of like elements are omitted for brevity.

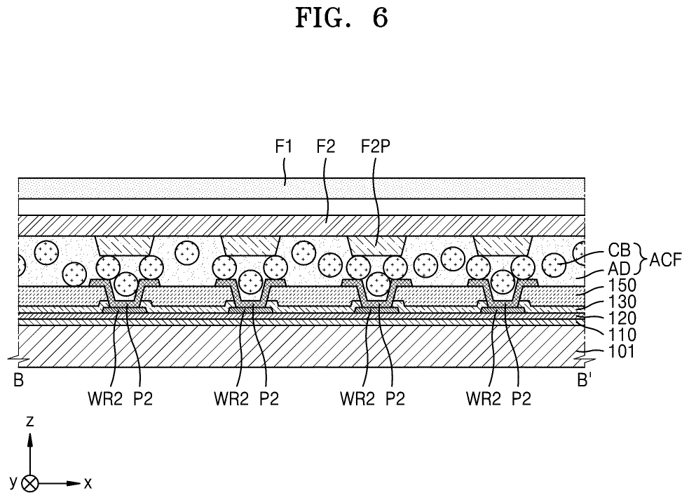

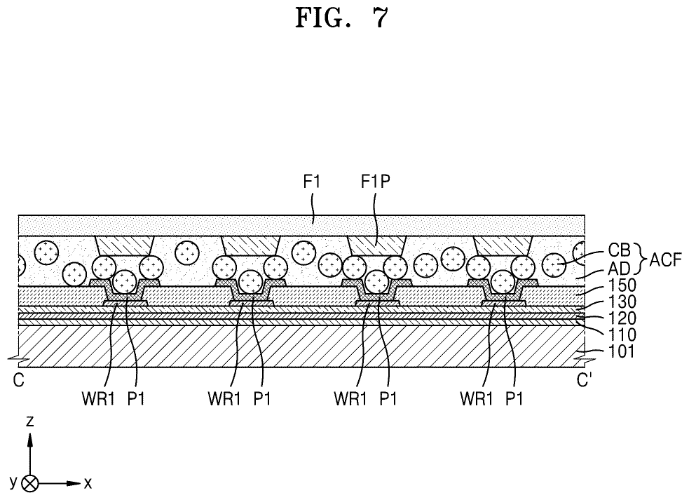

FIG. 6 is a schematic cross-sectional view of the display apparatus of FIG. 4 taken along a line B-B′, and FIG. 7 is a schematic cross-sectional view of the display apparatus of FIG. 4 taken along a C-C′. In addition to the first pads P1 and the second pads P2, layers such as, for example, a buffer layer 110, a first gate insulating layer 120, a second gate insulating layer 130, and an interlayer insulating layer 150 may be arranged on the first substrate 101, as illustrated in FIGS. 6 and 7.

The buffer layer 110 may be arranged between the first substrate 101 and a semiconductor layer of a thin-film transistor included in a pixel circuit in the main display area MDA and may extend to the main peripheral area MPA. The buffer layer 110 may include an inorganic material, such as, for example, silicon oxide, silicon nitride, and/or silicon oxynitride. The buffer layer 110 may improve the flatness of the upper surface of the first substrate 101 or prevent or reduce the penetration of impurities from the first substrate 101 to the semiconductor layer of the thin-film transistor.

The first gate insulating layer 120 may be between the semiconductor layer and a gate electrode disposed above the first gate insulating layer 120 and may extend to the main peripheral area MPA, similar to the buffer layer 110. The first gate insulating layer 120 may include an inorganic material, such as, for example, silicon oxide, silicon nitride, and/or silicon oxynitride.

The second gate insulating layer 130 may be between the gate electrode and a first conductive layer disposed above the second gate insulating layer 130, and the interlayer insulating layer 150 may be between the first conductive layer and a second conductive layer disposed above the interlayer insulating layer 150. The second gate insulating layer 130 and the interlayer insulating layer 150 may extend to the main peripheral area MPA, similar to the first gate insulating layer 120. The second gate insulating layer 130 and the interlayer insulating layer 150 may each include an inorganic material, such as, for example, silicon oxide, silicon nitride, and/or silicon oxynitride.

However, this is merely an example. Various insulating layers may be arranged on the first substrate 101 as applicable or suitable for the display apparatus, and conductive layers functioning as lines or connection electrodes may be arranged between the insulating layers. FIG. 6 illustrates an example in which second wires WR2 may be arranged between the first gate insulating layer 120 and the second gate insulating layer 130 and the second pads P2 on the interlayer insulating layer 150 are in contact with their corresponding second wires WR2. FIG. 7 illustrates an example in which first wires WR1 may be arranged between the second gate insulating layer 130 and the interlayer insulating layer 150 and the first pads P1 on the interlayer insulating layer 150 are in contact with their corresponding first wires WR1.

The second wire WR2 arranged between the first gate insulating layer 120 and the second gate insulating layer 130 may be simultaneously formed of the same material when, for example, the gate electrode of the thin-film transistor in the main display area MDA is formed. The first wire WR1 arranged between the second gate insulating layer 130 and the interlayer insulating layer 150 may be simultaneously formed of the same material when, for example, the first conductive layer in the main display area MDA is formed.

FIG. 4 does not show the first wires WR1 and the second wires WR2 for convenience, but as illustrated in FIGS. 6 and 7, the first wires WR1 connected to the first pads P1 and the second wires WR2 connected to the second pads P2 may be alternated in the second direction (the x-axis direction). Accordingly, the first wires WR1 and the second wires WR2, which are adjacent in the first direction (the x-axis direction), may be at different layers. Because of the arrangements described herein, when a greater number of first wires WR1 and second wires WR2 are aligned on the first substrate 101 at narrow intervals to implement the main display panel 10 capable of displaying high-resolution images, the occurrence of short circuits between the first wires WR1 and the second wires WR2 may be effectively prevented or reduced.

For reference, the first pads P1 and the second pads P2 may be simultaneously formed of the same material when the conductive layer on the interlayer insulating layer 150 in the main display area MDA is formed. In some aspects, the first pads P1 and the second pads P2 may each have multilayered structures. For example, the first pad P1 may have a multilayered structure of titanium/aluminum/titanium. Alternatively, the first pad P1 may have a multilayered structure of titanium/aluminum/titanium/ITO.

As illustrated in FIG. 6, second film pads F2P of the second film F2 may be electrically connected to their corresponding second pads P2, and as illustrated in FIG. 7, first film pads F1P of the first film F1 may be electrically connected to their corresponding first pads P1. To enable the electrical connection, anisotropic conductive films ACF may be arranged between the second film pads F2P and the second pads P2 and between the first film pads F1P and the first pads P1. The anisotropic conductive film ACF includes an adhesive member AD and conductive balls CB. Because of adhesive strength, the adhesive member AD may adhere a portion of the second film F2 to the first substrate 101 and a portion of the first film F1 to the first substrate 101. In this case, by placing the conductive balls CB between the second film pads F2P and the second pads P2, each of the second film pads F2P may be electrically connected to its corresponding second pad P2. Similarly, by placing the conductive balls CB between the first film pads F1P and the first pads P1, each of the first film pads F1P may be electrically connected to its corresponding first pad P1.

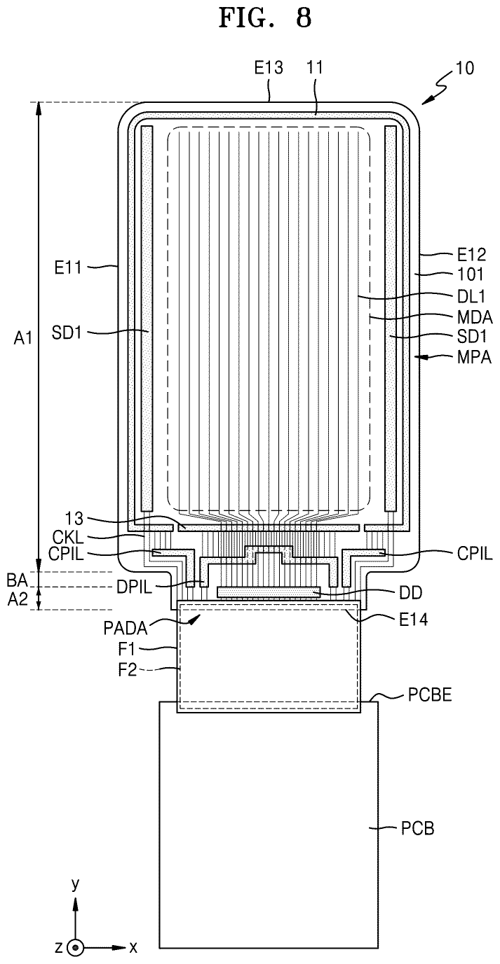

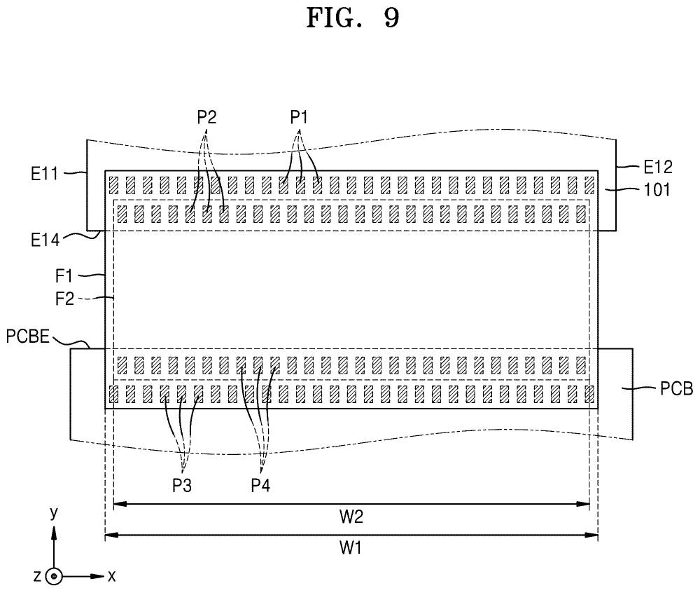

The embodiment in which the main display panel 10 is electrically connected to the sub-display panel 20 by using the first film F1 and the second film F2 overlapping each other is described, but one or more embodiments are not limited thereto. For example, as illustrated in FIGS. 8 and 9, FIG. 8 is a schematic plan view of a portion of a display apparatus and FIG. 9 is a schematic plan view of a portion of the display apparatus of FIG. 8, in which the display apparatus includes the main display panel 10 but omits the sub-display panel 20, and the main display panel 10 may be electrically connected to a printed circuit board PCB (that is not flexible) by using the first film F1 and the second film F2 that overlap each other. In a display apparatus equipped with both the main display panel 10 and the sub-display panel 20 in accordance with one or more embodiments of the present disclosure, the main display panel 10 may be electrically connected to the printed circuit board PCB by using two overlapping films. Hereinafter, a case where a display apparatus includes a main display panel 10 and omits the sub-display panel 20 is described.

The first pads P1 may be arranged on the first substrate 101 along the fourth main edge E14 of the first substrate 101 of the main display panel 10, and the second pads P2 may be arranged between the fourth main edge E14 and the first pads P1. The first pads P1 and the second pads P2 may be arranged along the fourth main edge E14, that is, in the second direction (the x-axis direction). The first pads P1 and the second pads P2 may not be covered by the insulating layer and may be exposed, thus being electrically connected to the first film F1 and/or the second film F2. For convenience of illustration, the first pads P1 and the second pads P2 are omitted from FIG. 8.

The third pads P3 and the fourth pads P4 may be arranged on the printed circuit board PCB. In detail, near printed circuit board edges PCBE that are edges of the printed circuit board PCB towards the first substrate 101, the third pads P3 may be arranged along the printed circuit board edges PCBE. The fourth pads P4 may be arranged between the printed circuit board edges PCBE and the third pads P3. The third pads P3 and the fourth pads P4 may be arranged along the printed circuit board edges PCBE, that is, in the second direction (the x-axis direction). For convenience of illustration, the third pads P3 and the fourth pads P3 are omitted from FIG. 8.

An end portion of the first film F1 (in the +y direction) may be electrically connected to the first pads P1 on the first substrate 101, and the other end portion of the first film F1 (in the −y direction) may be electrically connected to the third pads P3 on the printed circuit board PCB. An end portion of the second film F2 (in the +y direction) may be electrically connected to the second pads P2 on the first substrate 101, and the other end portion of the second film F2 (in the −y direction) may be electrically connected to the fourth pads P4 on the printed circuit board PCB. The first film F1 may include conductive lines, and the conductive lines may electrically connect the first pads P1 on the first substrate 101 to the third pads P3 on the printed circuit board PCB. The second film F2 may also include conductive lines, and the conductive lines may electrically connect the second pads P2 on the first substrate 101 to the fourth pads P4 on the printed circuit board PCB. That is, one conductive line of the first film F1 may electrically connect any one of the first pads P1 on the first substrate 101 to its corresponding one of the third pads P3 on the printed circuit board PCB. One conductive line of the second film F2 may electrically connect any one of the second pads P2 on the first substrate 101 to its corresponding one of the fourth pads P4 on the printed circuit board PCB.

On the printed circuit board PCB, a controller for controlling the overall operation of an electronic apparatus such as, for example, a display apparatus may be mounted. In association with transmitting an electrical signal from the controller or other components mounted to or included on the printed circuit board PCB to the main display panel 10, the first film F1 and the second film F2 may serve to deliver the electrical signal to the main display panel 10.

As illustrated in FIG. 9, the width W1 of the first film F1 may be greater than the width W2 of the second film F2 in the second direction (the x-axis direction). This width gap (e.g., difference between the width W1 and the width W2) prevents the second film F2 from being exposed outside the first film F1 such that it appears (e.g., according to a plan view) as if a single film is located between the main display panel 10 and the printed circuit board PCB. Thus, the probability of defects occurring during the manufacturing processes of the display apparatus may be reduced and manufacturing efficiency may be improved. Other descriptions regarding a display apparatus according to other embodiments described herein (e.g., with reference to FIG. 4) may be applied to the display apparatus according to the present embodiment. For example, the area of the first film F1 may be greater than the area of the second film F2, and the first film F1 may cover the second film F2. The location relationship between the first pads P1 and the second pads P2 and other aspects may also be applied to the display apparatus according to the present embodiment, and the placement of a portion of the second film F2, which overlaps the second pads P2, between the first substrate 101 and the first film F1 may also be applicable to the display apparatus according to the present embodiment. The first film F1 and the second film F2 are bent such that the rear surface of the printed circuit board PCB may face the rear surface of the first substrate 101.

According to the one or more embodiments, a display apparatus with a reduced peripheral area may be realized. However, the scope of the disclosure is not limited by the effects.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a first substrate;
first pads on the first substrate along a first edge of the first substrate;
second pads on the first substrate along the first edge, the second pads being between the first edge and the first pads;
a second substrate;
third pads on the second substrate along a second edge of the second substrate;
fourth pads on the second substrate along the second edge, the fourth pads being between the second edge and the third pads;
a first film comprising an end portion electrically connected to the first pads and another end portion electrically connected to the third pads; and
a second film comprising an end portion electrically connected to the second pads and another end portion electrically connected to the fourth pads.

2. The display apparatus of claim 1, wherein the first film overlaps the second film.

3. The display apparatus of claim 1, wherein a width in a second direction of the first film is greater than a width in the second direction of the second film, the second direction being perpendicular to a first direction which extends from the first substrate to the second substrate.

4. The display apparatus of claim 1, wherein an area of the first film is greater than an area of the second film.

5. The display apparatus of claim 1, wherein the first film covers the second film.

6. The display apparatus of claim 1, wherein a portion of the second film, which overlaps the second pads, is between the first substrate and the first film.

7. The display apparatus of claim 1, wherein a portion of the second film, which overlaps the fourth pads, is between the second substrate and the first film.

8. The display apparatus of claim 1, wherein the second pads correspond to spaces between the first pads.

9. The display apparatus of claim 1, wherein the fourth pads correspond to spaces between the third pads.

10. The display apparatus of claim 1, further comprising first display elements on the first substrate,
wherein the second substrate comprises a circuit board.

11. The display apparatus of claim 1, further comprising:
first display elements on the first substrate; and
second display elements on the second substrate.

12. The display apparatus of claim 11, further comprising a driving driver on the first substrate.

13. The display apparatus of claim 12, wherein the first film and the second film are configured to transmit electrical signals from the driving driver to the second display elements.

14. The display apparatus of claim 11, further comprising a flexible printed circuit board electrically connected to a third edge of the first substrate.

15. The display apparatus of claim 14, wherein the third edge is opposite to the first edge with respect to a center of the first substrate.

16. The display apparatus of claim 14, wherein the first film and the second film are configured to transmit electrical signals from the flexible printed circuit board to the second display elements.

17. The display apparatus of claim 11, wherein an area of a main display area of the first substrate, where the first display elements are arranged, is greater than an area of a sub-display area of the second substrate, where the second display elements are arranged.

18. The display apparatus of claim 17, wherein the first film and the second film are bendable such that a rear surface of the second substrate is on a rear surface of the first substrate.

19. The display apparatus of claim 1, wherein the first film and the second film are flexible.

20. The display apparatus of claim 1, wherein:
the first pads, the second pads, the third pads, and the fourth pads extend in a direction parallel to the first edge and the second edge; and
a width of the first film in the direction is greater than a width of the second film in the direction.
